(19) United States
(12) Patent Application Publication
(10) Pub. No.: US 2021/0249434 A1
(43) Pub. Date: Aug. 12, 2021

(54) SEMICONDUCTOR STORAGE DEVICE

(71) Applicant: Kioxia Corporation, Minato-ku (JP)

(72) Inventor: Takuya NISHIKAWA, Yokkaichi (JP)

(73) Assignee: Kioxia Corporation, Minato-ku (JP)

(21) Appl. No.: 16/944,552

(22) Filed: Jul. 31, 2020

(30) Foreign Application Priority Data
Feb. 7, 2020 (JP) 2020-020103

(51) Int. Cl. H01L 27/11582; H01L 27/11565; H01L 27/1157; H01L 23/528; H01L 23/522

(52) U.S. Cl. CPC H01L 27/11582; H01L 27/11565; H01L 23/5226; H01L 23/5283; H01L 27/1157

(57) ABSTRACT

A semiconductor storage device in an embodiment includes a stacked body including a plurality of conductive layers stacked with an insulating layer interposed therebetween, end portions of the plurality of conductive layers being arranged like stairs in a stair portion, a plurality of memory cells each disposed in a crossing portion of at least a part of the plurality of conductive layers and a pillar extending in a stacking direction of the plurality of conductive layers in the stacked body, a first structure having a longitudinal direction in a first direction crossing the stacking direction and dividing the stacked body, and a second structure disposed in the stair portion, extending in a second direction toward the first structure, extending in the stacking direction in the stacked body, and having a width wider at a first portion farther from the first structure than at a second portion closer to the first structure.

### CROSS-REFERENCE TO RELATED APPLICATIONS

This application is based upon and claims the benefit of priority from Japanese Patent Application No. 2020-020103, filed on Feb. 7, 2020; the entire contents of which are incorporated herein by reference.

### FIELD

Embodiments described herein relate generally to a semiconductor storage device.

### BACKGROUND

In a three-dimensional nonvolatile memory, memory cells are three-dimensionally arranged with respect to a stacked plurality of conductive layers. In such a configuration, an issue to be solved is how to keep the strength of a stacked structure.

### BRIEF DESCRIPTION OF THE DRAWINGS

FIGS. 1A and 1B are schematic diagrams illustrating a configuration example of a semiconductor storage device according to an embodiment;

FIGS. 2A and 2B are sectional views taken along a Y direction illustrating the configuration example of the semiconductor storage device according to the embodiment;

FIG. 3 is a perspective view of plate-like portions included in the semiconductor storage device according to the embodiment;

FIGS. 4A and 4B are diagrams illustrating sectional shapes taken along an X direction of a columnar portion and a beam portion included in the semiconductor storage device according to the embodiment;

FIGS. 5A and 5B are sectional views illustrating an example of a procedure of a manufacturing method for the semiconductor storage device according to the embodiment;

FIGS. 6A and 6B are sectional views illustrating the example of the procedure of the manufacturing method for the semiconductor storage device according to the embodiment;

FIGS. 7A and 7B are sectional views illustrating the example of the procedure of the manufacturing method for the semiconductor storage device according to the embodiment;

FIGS. 8A and 8B are sectional views illustrating the example of the procedure of the manufacturing method for the semiconductor storage device according to the embodiment;

FIGS. 9A and 9B are sectional views illustrating the example of the procedure of the manufacturing method for the semiconductor storage device according to the embodiment;

FIGS. 10A and 10B are sectional views illustrating the example of the procedure of the manufacturing method for the semiconductor storage device according to the embodiment;

FIGS. 11A and 11B are sectional views illustrating the example of the procedure of the manufacturing method for the semiconductor storage device according to the embodiment;

FIGS. 12A and 12B are sectional views illustrating the example of the procedure of the manufacturing method for the semiconductor storage device according to the embodiment;

FIGS. 13A to 13C are sectional views illustrating the example of the procedure of the manufacturing method for the semiconductor storage device according to the embodiment;

FIGS. 14A and 14B are sectional views illustrating the example of the procedure of the manufacturing method for the semiconductor storage device according to the embodiment;

FIGS. 15A and 15B are sectional views illustrating the example of the procedure of the manufacturing method for the semiconductor storage device according to the embodiment;

FIGS. 16A and 16B are sectional views illustrating the example of the procedure of the manufacturing method for the semiconductor storage device according to the embodiment;

FIGS. 17A and 17B are sectional views illustrating the example of the procedure of the manufacturing method for the semiconductor storage device according to the embodiment;

FIGS. 18A and 18B are sectional views illustrating the example of the procedure of the manufacturing method for the semiconductor storage device according to the embodiment;

FIGS. 19A and 19B are sectional views illustrating the example of the procedure of the manufacturing method for the semiconductor storage device according to the embodiment;

FIGS. 20A to 20E are cross sectional views in a height position of a plate-like portion of a semiconductor storage device according to a modification 1 of the embodiment;

FIGS. 21A to 21C are schematic diagrams illustrating shapes viewed from upper surfaces of plate-like portions included in, during a manufacturing process, a semiconductor storage device according to a modification 2 of the embodiment; and

FIGS. 22A to 22C are schematic diagrams illustrating shapes viewed from upper surfaces of original plates of mask patterns used during the manufacturing process of the semiconductor storage device according to the modification 2 of the embodiment.

### DETAILED DESCRIPTION

A semiconductor storage device in an embodiment includes: a stacked body including a plurality of conductive layers stacked with an insulating layer interposed therebetween, end portions of the plurality of conductive layers being arranged like stairs in a stair portion; a pillar extending in a stacking direction of the plurality of conductive layers in the stacked body; a plurality of memory cells each disposed in a crossing portion of at least a part of the plurality of conductive layers and the pillar; a first structure that has a longitudinal direction in a first direction crossing the stacking direction and divides the stacked body; and a second structure that is disposed in the stair portion, extends in a second direction toward the first structure from a position apart from a side surface of the first structure and extends in the stacking direction in the stacked body. A width of the second structure is wider at a first portion farther from the first structure than at a second portion closer to the first structure. The second portion has a longitudinal direction in the second direction in top view.

The present invention will be explained below in detail with reference to the drawings. The present invention is not limited to the following embodiment. Components in the embodiment include components that those skilled in the art can easily assume or components substantially the same as the components.

(Configuration Example of a Semiconductor Storage Device)

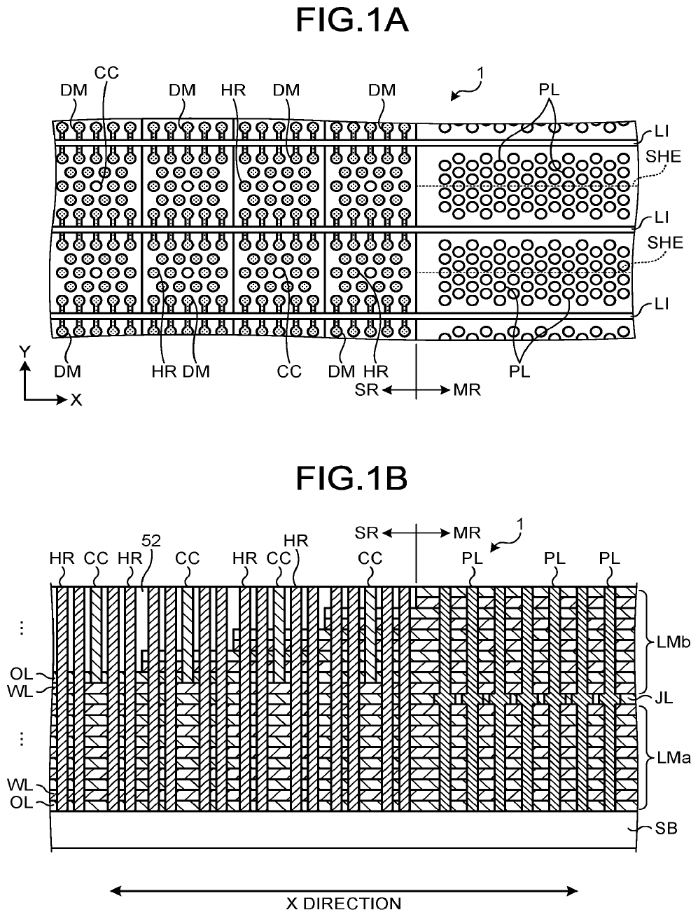

FIGS. 1A and 1B are schematic diagrams illustrating a configuration example of a semiconductor storage device 1 according to the embodiment. FIG. 1A is a top view of a semiconductor storage device 1 and FIG. 1B is a sectional view taken along an X direction of the semiconductor storage device 1. In FIGS. 1A and 1B, an upper layer wire and the like for a pillar PL and the like are omitted. In FIG. 1A, an insulating layer 52 and the like that cover the entire structure of the illustrated portion are omitted.

As illustrated in FIGS. 1A and 1B, the semiconductor storage device 1 includes, on a substrate SB such as a silicon substrate, stacked bodies LMa and LMb in which a plurality of word lines WL as conductive layers and a plurality of insulating layers OL are alternately stacked. The stacked body LMb is disposed on the stacked body LMa via a joining layer JL. The word line WL is, for example, a tungsten layer or a molybdenum layer. The insulating layer OL and the joining layer JL are, for example, an SiO₂ layer.

Note that, in the example illustrated in FIG. 1B, each of the stacked bodies LMa and LMb includes five layers of the word lines WL. However, the number of layers of the word lines WL is optional. The stacked body LMa may be configured by disposing a selective gate line (not illustrated) below the word line WL in the bottom layer. The stacked body LMb may be configured by disposing a selective gate line (not illustrated) above the word line WL in the top layer.

The stacked bodies LMa and LMb include a memory region MR in which a plurality of memory cells is three-dimensionally arranged and a stair portion SR in which end portions of the stacked bodies LMa and LMb are arranged like stairs. The stacked bodies LMa and LMb are divided by contacts LI as first structures extending in an X direction. That is, longitudinal directions of the contacts LI are in the X direction. The memory regions MR and the stair portions SR are divided into a plurality of regions called blocks by these contacts LI. In the memory region MR, further above the word line WL in the top layer of the stacked body LMb, belt-like insulating members SHE (indicated by dotted lines in FIG. 1A) extending in the X direction are disposed in a Y direction alternately with the contacts LI and, for example, divide the conductive layers above the word line WL in the top layer into patterns of selective gate lines (not illustrated).

In the memory region MR, a plurality of pillars PL penetrating through the stacked bodies LMa and LMb is arranged in a matrix shape. A plurality of memory cells is formed on side surfaces of the pillars PL. Detailed configurations of the pillars PL and the memory cells are explained below.

The stair portion SR is adjacent to the memory region MR in the X direction and has a stair-like structure rising toward the memory region MR. Steps of the stair portion SR are covered with the insulating layer 52 to be at substantially the same height as the upper surface of the stacked body LMb in the memory region MR. Note that, in this specification, a direction in which terrace surfaces of the steps of the stair portion SR face is specified as an upward direction.

In the stair portion SR, the word lines WL respectively connected to the memory cells arranged in the height direction are led out like stairs. The word lines WL in the steps are connected to contacts CC disposed in the steps of the stair portion SR.

In the stair portion SR, a plurality of columnar bodies HR penetrating through the insulating layer 52 and the stacked bodies LMa and LMb is arranged in a matrix shape. The columnar bodies HR support a stacked structure of the semiconductor storage device 1 being manufactured in a manufacturing process for the semiconductor storage device 1 explained below.

In the stair portion SR, in the vicinity of the contacts LI on both sides of the contacts LI, a plurality of plate-like portions DM as a plurality of second structures is disposed along the contacts LI extending in the X direction. The plate-like portions DM extend in the Y direction, and one ends of the plate-like portions DM are in contact with the contacts LI. That is, longitudinal directions of the plate-like portions DM in the top view of FIG. 1A are in the Y direction. The plate-like portions DM disposed on both sides of the contacts LI are opposed to each other with the contacts LI interposed therebetween.

The other ends of the plate-like portions DM farther from the contacts LI have a width larger than the width at the one ends in contact with the contacts LI. In other words, the plate-like portions DM have a shape obtained by connecting structures similar to the columnar bodies HR to the other ends. According to such perception, it can be said that the other ends of the plate-like portions DM have expanded diameters.

In the following explanation, concerning the shape of the other end portions of the plate-like portions DM, by grasping this as extension of main body portions of the plate-like portions DM extending like a plate and an expression such as “the other end portions have predetermined “width” may be used, or by grasping the shape of the other end portions as a shape like the columnar bodies HR and an expression such as “the other end portions have predetermined “diameter”” may be used.

Note that, although not illustrated in FIGS. 1A and 1B, the semiconductor storage device 1 includes, for example, a peripheral circuit including a transistor disposed on the substrate SB. The peripheral circuit contributes to the operation of the memory cell.

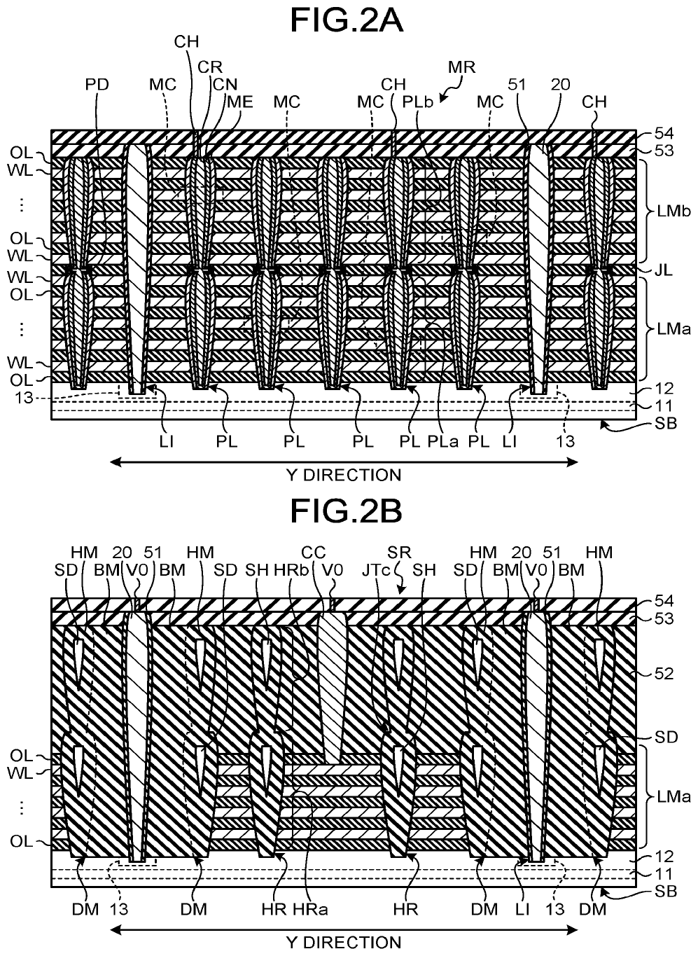

FIGS. 2A and 2B are sectional views taken along the Y direction illustrating a configuration example of the semiconductor storage device 1 according to the embodiment. FIG. 2A is a sectional view of the memory region MR. FIG. 2B is a sectional view of the stair portion SR.

As illustrated in FIGS. 2A and 2B, the substrate SB such as a silicon substrate includes an n well 11 in a surface layer portion, includes a p well 12 in the n well 11, and includes a plurality of n⁺ diffused regions 13 in the p well 12.

As illustrated in FIG. 2A, in the memory region MR, the stacked body LMa is disposed on the substrate SB, the joining layer JL is disposed on the stacked body LMa, and the stacked body LMb is disposed on the joining layer JL. An insulating layer 53 is disposed on the stacked body LMb. An insulating layer 54 is disposed on the insulating layer 53.

The plurality of contacts LI penetrates through the insulating layer 53, the stacked bodies LMa and LMb, and the joining layer JL and are disposed on the n⁺ diffused region 13 of the substrate SB. The contacts LI sometimes have, for example, a bowing shape having a large width in a predetermined position below the upper surface and having a small width of the bottom surface compared with the width of the upper surface.

Each of the contacts LI includes an insulating layer 51 that covers a sidewall of the contact LI. A conductive layer 20 is filled inside the insulating layer 51. The insulating layer 51 is, for example, an SiO₂ layer or the like. The conductive layer 20 is, for example, a polysilicon layer, a tungsten layer or the like. The conductive layer 20 of the contact LI are connected to the upper layer wire via a plug V0 (see FIG. 2B) penetrating through the insulating layer 54.

The contact LI including the conductive layer 20 connected to the plug V0 is disposed on the n⁺ diffused region 13 of the substrate SB, whereby the contact LI functions as, for example, source line contacts. However, instead of the contact LI, an insulating layer such as an SiO₂ layer may divide the stacked bodies LMa and LMb in the Y direction.

A plurality of pillars PL is arranged in a matrix shape in the stacked bodies LMa and LMb between two contacts LI. Each of the pillars PL penetrates through the stacked bodies LMa and LMb and the joining layer JL and reaches the substrate SB.

Each of the pillars PL has a shape obtained by joining, in a height position of the joining layer JL, a pillar PLa, which is a structure penetrating through the stacked body LMa, and a pillar PLb, which is a structure penetrating through the stacked body LMb. The pillars PLa and PLb sometimes have, for example, a bowing shape having a large diameter in a predetermined position below the upper surface and having a small diameter of the bottom surface compared with the diameter of the upper surface.

Each of the pillars PL includes a pedestal PD having an expanded diameter in a joined portion in the joining layer JL. The pedestal PD has a diameter larger than the diameter of the bottom surface of the pillar PLb disposed in the stacked body LMb.

Each of the pillars PL includes, in order from the outer circumferential surface side, a memory layer ME, a channel layer CN, and a core layer CR. The channel layer CN is disposed in the bottom of the pillar PL as well. The memory layer ME is, for example, a layer in which an SiO₂ layer/an SiN layer/an SiO₂ layer are stacked. The channel layer CN is, for example, an amorphous silicon layer, a polysilicon layer or the like. The core layer CR is, for example, an SiO₂ layer or the like.

The channel layer CN of the pillar PL is connected to the upper layer wire such as a bit line via a plug CH penetrating through the insulating layers 53 and 54. Each of the pillars PL includes the memory layer ME in which an SiN layer functioning as a charge storage portion is surrounded by insulating layers such as an SiO₂ layer functioning as a tunnel layer and a block layer and the channel layer CN connected to the plug CH. Consequently, a memory cell MC is formed in each crossing portion of the pillar PL and the word lines WL.

However, among five pillars PL arranged between two contacts LI, a part of the pillars PL such as the pillar PL in the center does not include the plug CH. Such a pillar PL is disposed to maintain regular array of the plurality of pillars PL. Memory cells are not formed on side surfaces of the pillars PL or a function of memory cells on the side surfaces are ineffective. In an upper portion of the pillar PL in the center, an insulating member SHE (see FIG. 1A) is formed to extend in the X direction and cross the pillar PL in the center and divides a conductive layer (not illustrated) disposed further above the word line WL in the top layer of the stacked body LMb into two selective gate lines adjacent in the Y direction between two contacts LI.

As explained above, in the memory region MR, a plurality of memory cells MC is three-dimensionally arranged. That is, the semiconductor storage device 1 is configured as, for example, a three-dimensional nonvolatile memory.

On the other hand, in the stair portion SR, a sectional structure is different depending on the position of the stair portion SR. In a position most distant from the memory region MR, the word line WL and the insulating layer OL in the bottom layer of the stacked body LMa are disposed on the substrate SB. The stacked body LMa on the substrate SB have more layers toward the memory region MR. Further, layers of the stacked body LMb are disposed via the joining layer JL. In a position closest to the memory region MR, the word line WL and the insulating layer OL in the top layer of the stacked body LMb are disposed.

The insulating layer 52 covers substantially the entire stair portion SR, for example, up to a height position of the top layer of the stacked body LMb. The insulating layer 53 is disposed on the insulating layer 52. The insulating layer 54 is disposed on the insulating layer 53.

FIG. 2B illustrates a stair portion SR in a fourth step from the bottom. The stair portion SR in the fourth step is configured by four sets of the word lines WL and the insulating layers OL excluding the insulating layer OL in the bottom layer. To the fourth word line WL from the bottom forming the top layer in the stair portion SR in the fourth step, a contact CC penetrating through the insulating layer OL on the word line WL and the insulating layers 52 and 53 is connected. The contact CC is connected to the upper layer wire via the plug V0 penetrating though the insulating layer 54.

A plurality of columnar bodies HR is disposed around the contact CC. In a position illustrated in FIG. 2B, each of the columnar bodies HR penetrates through the stair portion in the fourth step of the stacked body LMa from the upper surface of the insulating layer 52 and reaches the substrate SB.

Each of the columnar bodies HR has a shape obtained by joining, in the height position equivalent to the joining layer JL, a columnar body HRa reaching the substrate SB from a height position equivalent to the joining layer JL and a columnar body HRb reaching the height position equivalent to the joining layer JL in the insulating layer 52. The columnar bodies HRa and HRb sometimes have, for example, a bowing shape having a large diameter in a predetermined position below the upper surface and having a small diameter of the bottom surface compared with the diameter of the upper surface.

Each of the columnar bodies HR includes a joining portion JTc in a joined portion. In the joining portion JTc, the bottom surface of the columnar body HRb is connected to the upper surface of the columnar body HRa. The upper surface of the columnar body HRa has a diameter larger than the diameter of the bottom surface of the columnar body HRb. However, like the pillar PL, the columnar body HR may include a pedestal having an expanded diameter in the joined portion.

In each of the columnar bodies HR, an insulating layer such as an SiO₂ layer is filled. The columnar body HR sometimes includes a void SH, in which the insulating layer is not filled, in a portion corresponding to cores of the columnar bodies HRa and HRb. The void SH can be opened on the upper surfaces of the columnar bodies HRa and HRb.

The plurality of plate-like portions DM is disposed on both sides in the Y direction of the contact LI. In the position illustrated in FIG. 2B, each of the plate-like portions DM penetrates through the stair portion SR in the fourth step of the stacked body LMa from the upper surface of the insulating layer 52 and reaches the substrate SB.

Each of the plate-like portions DM includes a set of a columnar portion HM and a beam portion BM. The columnar portion HM is equivalent to a portion with an expanded diameter illustrated in the top view of FIG. 1A and is disposed in a position away from the contact LI. The diameter of the columnar portion HM is substantially equal to, for example, the diameter of the columnar body HR. One end of the beam portion BM is connected to a side surface of the columnar portion HM facing the contact LI side. The other end of the beam portion BM is connected to the side surface of the contact LI.

However, the columnar portion HM and the beam portion BM are integrally formed. A boundary between the columnar portion HM and the beam portion BM cannot be identified in a cross section taken along the Y direction illustrated in FIG. 2B. In FIG. 2B, for convenience, a side surface of the columnar portion HM close to the beam portion BM is indicated by a dotted line. The columnar portion HM and the beam portion BM also have upper and lower structures joined in the height position equivalent to the joining layer JL.

In each of the plate-like portions DM, an insulating layer such as an SiO₂ layer is filled. The plate-like portions DM sometimes includes a void SD, in which the insulating layer is not filled, in a portion corresponding to a core of the columnar portion HM. The void SD can be opened on the respective upper surfaces in the upper and lower structures of the columnar portion HM.

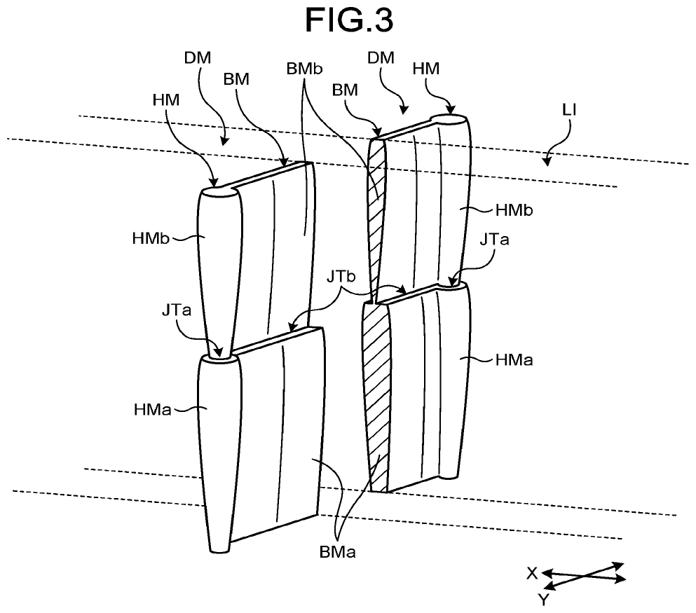

FIG. 3 is a perspective view of the plate-like portions DM included in the semiconductor storage device 1 according to the embodiment. In FIG. 3, two plate-like portions DM located in positions opposed to each other with the contact LI interposed therebetween are illustrated. In FIG. 3, the contact LI separating the two plate-like portions DM is indicated by dotted lines.

As illustrated in FIG. 3, the columnar portion HM has the same shape as the shape of the columnar body HR explained above. That is, the columnar portion HM has a shape obtained by joining, in the height position equivalent to the joining layer JL, a columnar portion HMa reaching the substrate SB from a height position equivalent to the joining layer JL and a columnar portion HMb reaching the height position equivalent to the joining layer JL in the insulating layer 52. The columnar portions HMa and HMb sometimes have, for example, a bowing shape having a large diameter in a predetermined position below the upper surface and having a small diameter of the bottom surface compared with the diameter of the upper surface.

Each of the columnar portions HM includes a joining portion JTa in a joined portion. In the joining portion JTa, the bottom surface of the columnar portion HMb is connected to the upper surface of the columnar portion HMa. The upper surface of the columnar portion HMa has a diameter larger than the diameter of the bottom surface of the columnar portion HMb. However, like the pillar PL, the columnar portion HM may include a pedestal having an expanded diameter in the joined portion.

The beam portion BM has a shape obtained by joining, in the height position equivalent to the joining layer JL, a beam portion BMa reaching the substrate SB from a height position equivalent to the joining layer JL and a beam portion BMb reaching the height position equivalent to the joining layer JL in the insulating layer 52. The beam portions BMa and BMb sometimes have, for example, a bowing shape having a large width in a predetermined position below the upper surface and having a small width of the bottom surface compared with the width of the upper surface.

Each of the beam portions BM includes a joining portion JTb in a joined portion. In the joining portion JTb, the bottom surface of the beam portion BMb is connected to the upper surface of the beam portion BMa. The upper surface of the beam portion BMa has a width larger than the width of the bottom surface of the beam portion BMb. However, like the pillar PL, the beam portion BM may include a pedestal having an expanded width in the joined portion.

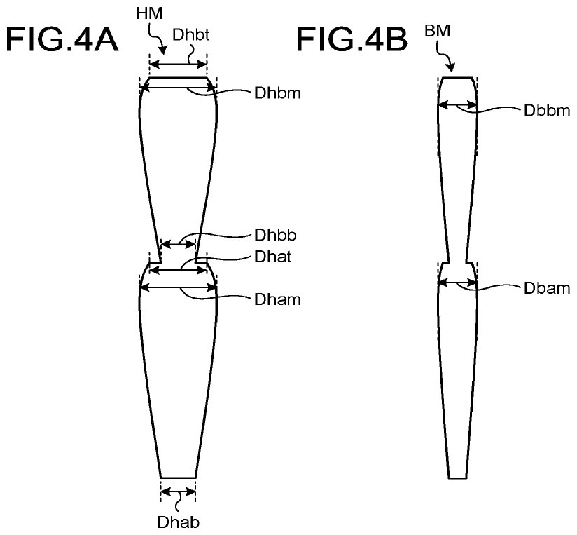

FIGS. 4A and 4B are diagrams illustrating sectional shapes taken along the X direction of the columnar portion HM and the beam portion BM included in the semiconductor storage device 1 according to the embodiment. FIG. 4A illustrates a sectional shape of the columnar portion HM. FIG. 4B illustrates a sectional shape of the beam portion BM.

As illustrated in FIGS. 4A and 4B, it is assumed that the upper surface of the columnar portion HMb has a diameter Dhbt, a most bulging portion of the columnar portion HMb has a diameter Dhbm, and the bottom surface of the columnar portion HMb has a diameter Dhbb. It is assumed that the most bulging portion of the beam portion BMb has a width Dbbm. Note that the diameter Dhbb can be a minimum diameter of the columnar portion HMb.

In the plate-like portions DM in the embodiment, the diameter Dhbb, which is the minimum diameter, is preferably larger than the width Dbbm. In process design, a value of the diameter Dhbb can be controlled according to the diameter Dhbt. Therefore, the diameter Dhbt is preferably larger than the width Dbbm. The diameter Dhbt can be set to a double or more of the width Dbbm.

Consequently, the following relation can hold about the diameters Dhbt and Dhbb and the width Dbbm.

Diameter Dbbt>diameter Dhbb>width Dbbm

It is assumed that the upper surface of the columnar portion HMa has a diameter Dhat, a most bulging portion of the columnar portion HMa has a diameter Dham, and the bottom surface of the columnar portion HMa has a diameter Dhab. It is assumed that a most bulging portion of the beam portion BMa has a width Dbam. Note that the diameter Dhab can be a minimum diameter of the columnar portion HMa. At this time, concerning the portions of the columnar portion HMa and the beam portion BMa, the same relation as the relation among the portions of the columnar portion HMb and the beam portion BMb can hold.

That is, in the plate-like portions DM in this embodiment, the diameter Dhab, which is the minimum diameter, is preferably larger than the width Dbam. In process design, a value of the diameter Dhab can be controlled according to the diameter Dhat. Therefore, the diameter Dhat is preferably larger than the width Dbam. The diameter Dhat can be set to, for example, a double or more of the width Dbam.

Consequently, the following relation can hold about the diameters Dhat and Dhab and the width Dbam.

Diameter Dhat>diameter Dhab>width Dbam

Note that the diameters of the respective columnar portions HMa and HMb may have the following relation.

Diameter Dhbt>diameter Dhat, diameter Dhbm>diameter Dham, diameter Dhbb>diameter Dhab

That is, the diameter of the columnar portion HM decreases as a whole toward the lower layer throughout the entire stacked bodies LMa and LMb.

The widths of the respective beam portions BMa and BMb may have the following relation.

Width Dbbm>width Dbam

That is, the width of the beam portion BM decreases as a whole toward the lower layer throughout the entire stacked bodies LMa and LMb.

(Manufacturing Method for the Semiconductor Storage Device)

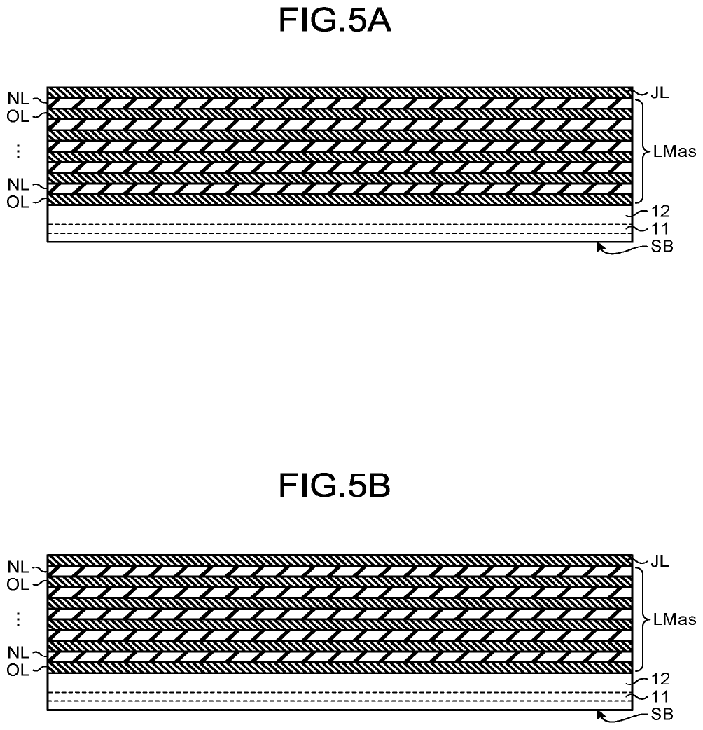

An example of a manufacturing method for the semiconductor storage device 1 in the embodiment is explained with reference to FIGS. 5A to 19B.

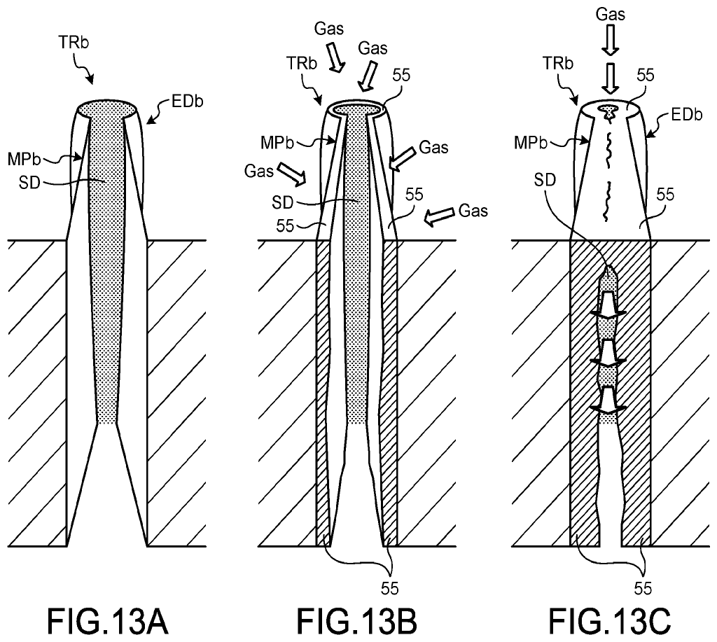

FIGS. 5A to 19B are sectional views illustrating an example of a procedure of the manufacturing method for the semiconductor storage device 1 according to the embodiment. Except FIGS. 13A to 13C, A and B in the same figure numbers indicate different cross sections in the same processing step. A in FIGS. 5A to 19B excluding FIGS. 13A to 13C is equivalent to a part illustrated in FIGS. 2A and B in FIGS. 5A to 19B excluding FIGS. 13A to 13C is equivalent to a part in FIG. 2B.

As illustrated in FIGS. 5A and 5B, a stacked body LMas in which a plurality of sacrificial layers NL and a plurality of insulating layers OL are alternately stacked is formed on the substrate SB, in the surface portion of which the n well 11, the p well 12, and the like are formed. The sacrificial layers NL are insulating layers such as SiN layers and are layers that are replaced with a conductive material to be the word lines WL. The joining layer JL is formed on the stacked body LMas.

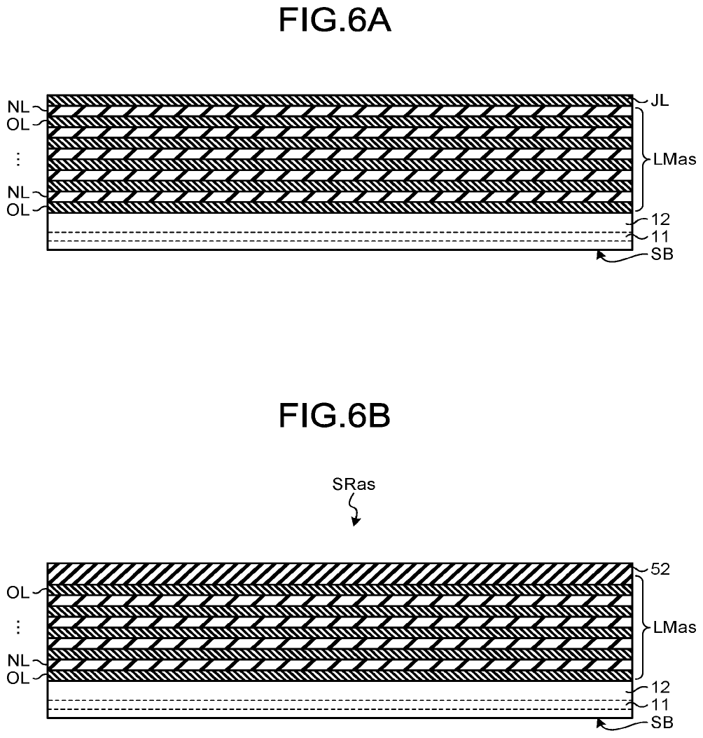

As illustrated in FIG. 6B, a stair portion SRas is formed on the stacked body LMas. The stair portion SRas includes a stair in a lower portion formed by the stacked body LMas in an entire stair-like structure. In a position illustrated in FIG. 6B, the joining layer JL and the sacrificial layer NL in the top layer of the stacked body LMas are removed. A stair portion in a fourth step from the bottom is formed. In a step portion of the stair portion SRas, for example, the insulating layer 52 is formed up to the height of the upper surface of the joining layer JL.

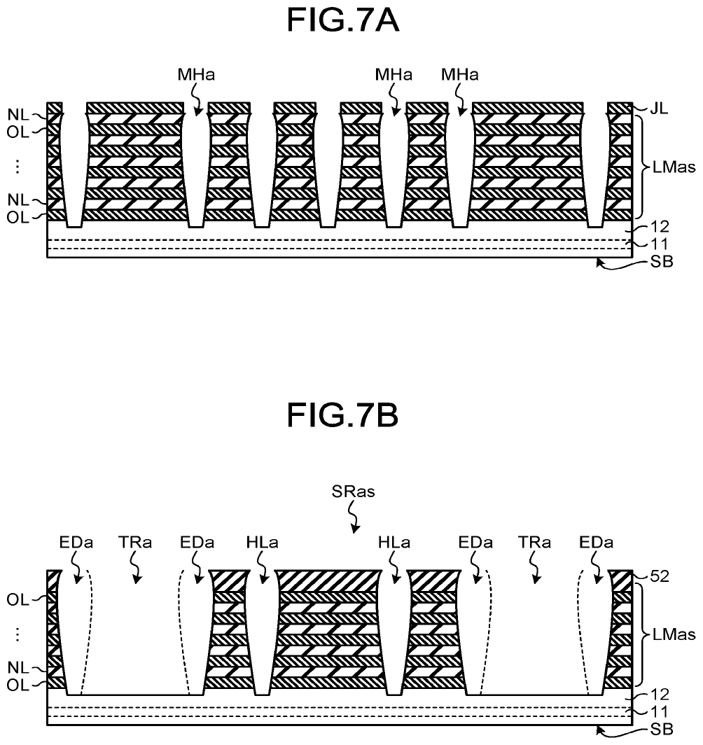

As illustrated in FIG. 7A, memory holes MHa are formed in the stacked body LMas. The memory holes MHa penetrate through the joining layer JL and the stacked body LMas and reach the substrate SB. The memory holes MHa each have, for example, a bowing shape and an expanded diameter at the joining layer JL.

As illustrated in FIG. 7B, holes HLa and trenches TRa are formed in the stair portion SRas. The holes HLa and the trenches TRa penetrate through the insulating layer 52 and the stacked body LMas and reach the substrate SB. In a position illustrated in FIG. 7B, the holes HLa and the trenches TRa penetrate through the insulating layer 52 and a stair in a fourth step of the stair portion SRas.

Note that both end portions EDa of the trenches TRa have expanded diameters. The width of both the end portions EDa with the expanded diameters is, for example, size in the same degree as the diameter of the holes HLa. The holes HLa and main body portions and both the end portions EDa of the trenches TRa have, for example, a bowing shape.

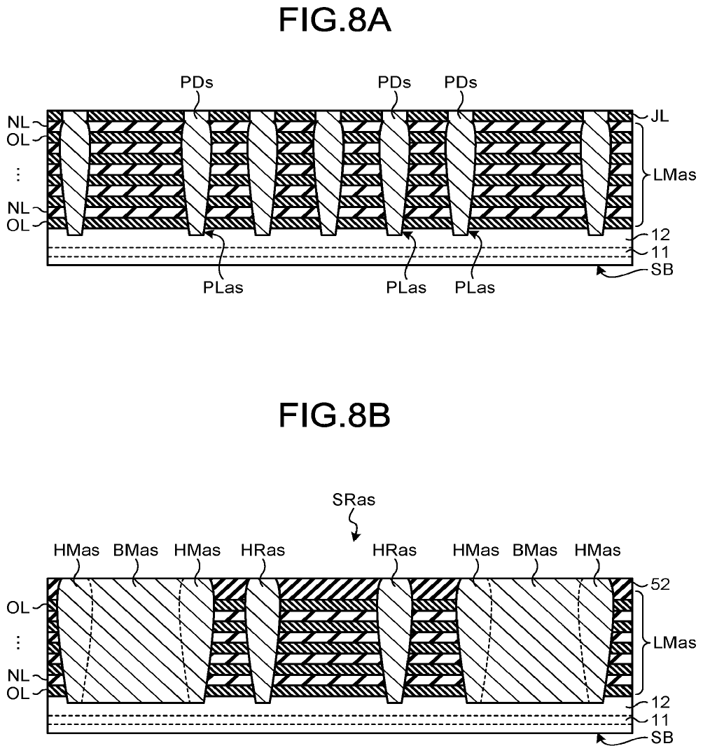

As illustrated in FIG. 8A, pillars PLas and pedestals PDs are formed by filling a sacrificial layer in the memory holes MHa. That is, a sacrificial layer such as an amorphous silicon layer is filled inside the memory holes MHa having upper parts with expanded diameters. Consequently, the pillars PLas including the pedestals PDs at upper end portions are formed.

As illustrated in FIG. 8B, columnar bodies HRas are formed by filling a sacrificial layer in the holes HLa and columnar portions HMas and beam portions BMas are formed by filling a sacrificial layer in the trenches TRa. That is, a sacrificial layer such as an amorphous silicon layer is filled on the inner sides of the holes HLa and the trenches TRa. Consequently, the columnar bodies HRas, the columnar portions HMas, and the beam portions BMas are formed.

Note that the beam portions BMas to be divided by the contacts LI later are connected into one portion at this stage. The columnar portions HMas are respectively connected to the beam portions BMas at both end portions thereof.

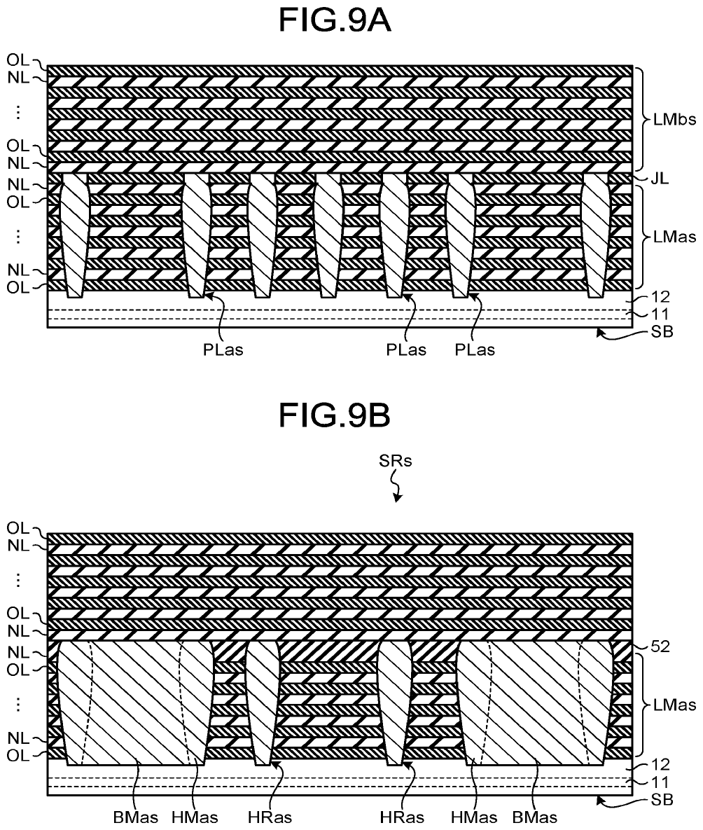

As illustrated in FIGS. 9A and 9B, a stacked body LMbs in which a plurality of sacrificial layers NL and a plurality of insulating layers OL are alternately stacked is formed on upper layers of the portions. That is, in a part illustrated in FIG. 9A, the stacked body LMbs is formed on the stacked body LMas via the joining layer JL. In a part illustrated in FIG. 9B, the stacked body LMbs is formed on the insulating layer 52.

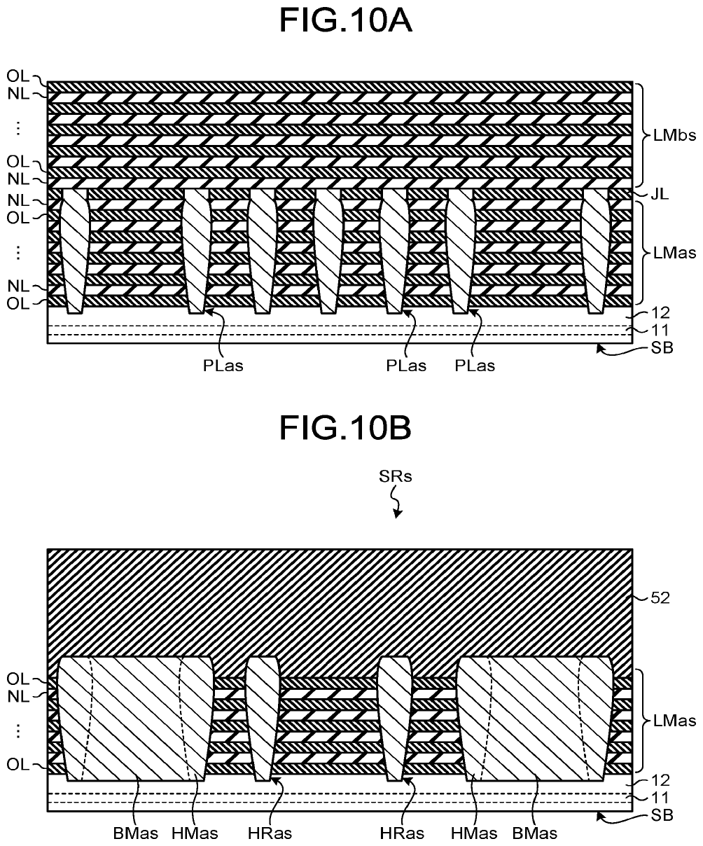

As illustrated in FIG. 10B, the stacked body LMbs is processed and a stair portion SRs including the stair portion SRas of the stacked body LMas is formed. The stair portion SRs includes an entire stair-like structure formed by the stacked bodies LMas and LMbs. In a position illustrated in FIG. 10B, the entire stacked body LMbs is removed and a stair portion SRs at a fourth step from the bottom is left. In the stair portion SRs, for example, the insulating layer 52 is formed up to the height of the upper surface of the stacked body LMbs.

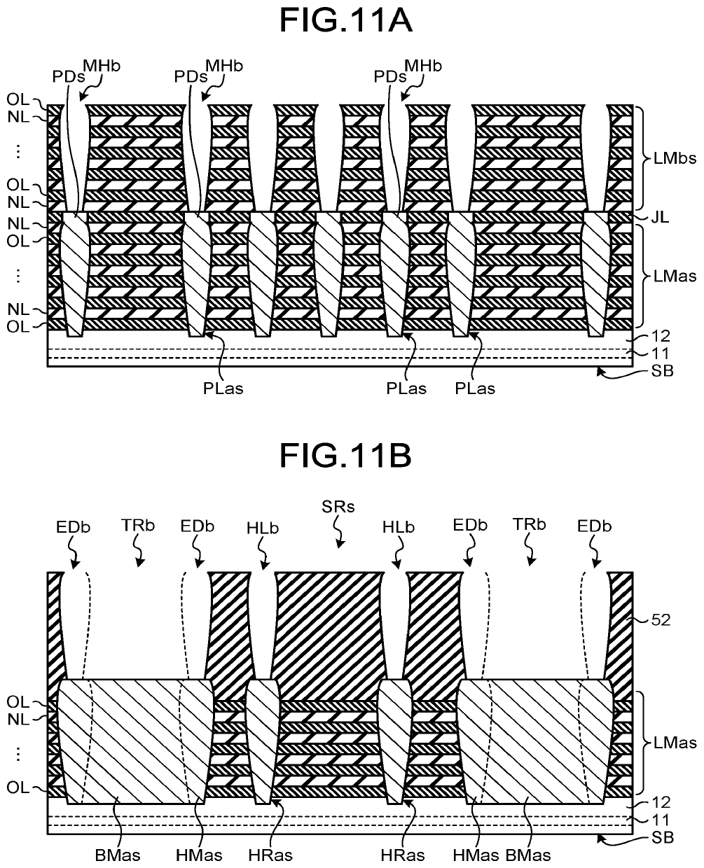

As illustrated in FIG. 11A, memory holes MHb are formed in the stacked body LMbs. The memory holes MHb penetrate through the stacked body LMbs and are connected to the respective pedestals PDs of the joining layer JL. Since the diameter of the pedestals PDs is expanded in the joining layer JL, even if disposition positions of the pillars PLas and disposition positions of the memory holes MHb do not completely coincide in upper and lower positions because of misalignment or the like, the memory holes MHb and the pillars PLas can be connected via the pedestals PDs. The memory holes MHb have, for example, a bowing shape.

As illustrated in FIG. 11B, holes HLb and trenches TRb are formed in the stair portion SRs. The holes HLb and the trenches TRb penetrate through the insulating layer 52 and the stacked body LMbs and reach a height position equivalent to the joining layer JL. The holes HLb are connected to the respective columnar bodies HRas.

Both end portions EDb of the trenches TRb have expanded diameters. The width of both the end portions EDb with the expanded diameters is, for example, size in the same degree as the diameter of the holes HLb. In a reaching position equivalent to the joining layer JL, main body portions of the trenches TRb are connected to the beam portions BMas. Both the end portions EDb are respectively connected to the columnar portions HMas.

Note that the holes HRb and the main body portions and both the end portions EDb of the trenches TRb have, for example, a bowing shape. In process characteristics, for example, it is sometimes easier to generate bowing in the insulating layer 52 formed by a single layer than in the stacked bodies LMas and LMbs in which the insulating layers OL and the sacrificial layers NL are stacked.

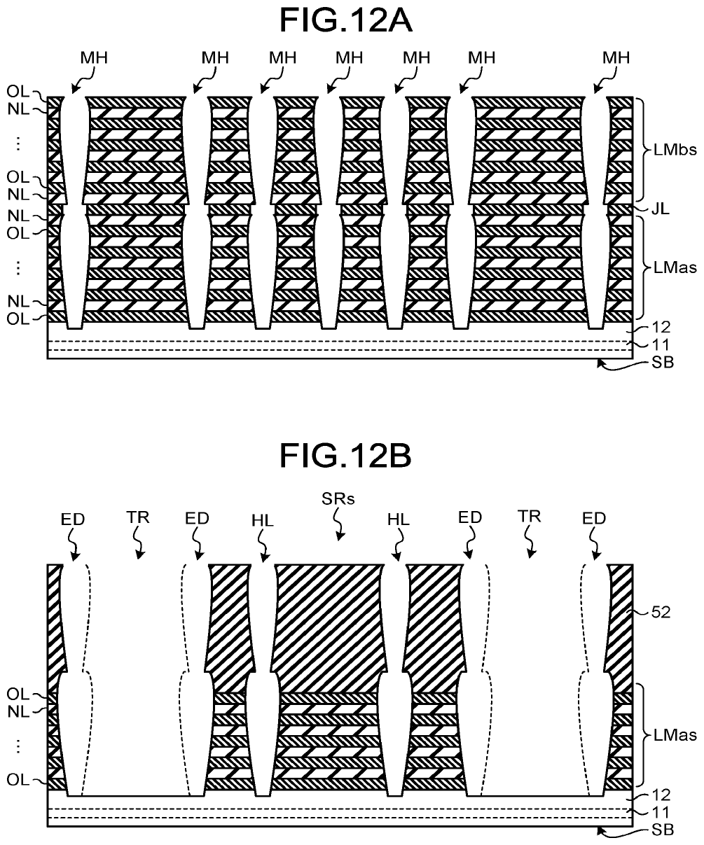

As illustrated in FIG. 12A, the sacrificial layer filled in the memory holes MHa is removed via the memory holes MHb. Consequently, memory holes MH that penetrate through the stacked body LMbs, the joining layer JL, and the stacked body LMas and reach the substrate SB are formed.

As illustrated in FIG. 12B, the sacrificial layer filled in the holes HLa and the trenches TRa is removed via holes HLb and the trenches TRb. Consequently, holes HL and trenches TR with the expanded diameters at both the end portions ED reaching the substrate SB from the upper surface of the insulating layer 52 are formed. Thereafter, in a state in which the memory holes MH illustrated in FIG. 12A are closed by masks, an insulating layer such as an SiO₂ layer is filled in the holes HL and the trenches TR.

FIGS. 13A to 13C are a perspective sectional view illustrating the example of the procedure of the manufacturing method for the semiconductor storage device 1 according to the embodiment. FIGS. 13A to 13C illustrate states in which an insulating layer 55 is formed in the trench TRb including both end portions EDb with expanded diameters.

FIG. 13A illustrates a cross section taken along the X direction of a main body portion MPb of the trench TRb, which is an upper structure of the trench TR and illustrates a state in which a Y direction, that is, one end portion EDb with an expanded diameter is generally viewed from this cross section. In FIG. 13A, a region with dot-like hatching indicates the void SD in an end portion EDb having a substantially cylindrical shape. Before the insulating layer 55 is formed, the void SD is opened from a cylindrical side surface portion of the end portion EDb toward the main body portion MPb.

As illustrated in FIG. 13B, when a material gas for an insulating layer 55 is supplied, the insulating layer 55 is formed on inner wall surfaces of the end portion EDb and the main body portion MPb. The insulating layer 55 is formed in a direction substantially perpendicular to the inner wall surfaces of the end portion EDb and the main body portion MPb.

As illustrated in FIG. 13C, when the supply of the material gas is continued, the upper end portion of the main body portion MPb opened upward is substantially closed by the insulating layer 55. At this time, an unfilled portion remains in a lower part of the main body portion MPb. This is because a supply amount of the material gas decreases from an upper part toward a lower part of the main body portion MPb and film forming speed of the insulating layer 55 also decreases.

On the other hand, the supply amount of the material gas increases and the insulating layer 55 is formed thicker in an upper part of the end portion EDb as well. However, the diameter of the end portion EDb is larger than the width of the main body portion MPb. More specifically, for example, the diameter of the upper end portion, the diameter of the most bulging portion, and the diameter of the bottom of the end portion EDb and the width of the most bulging portion of the main body portion MPb are in the same relation as the relation between the diameter of the columnar portion HMb and the width of the beam portion BMb.

Therefore, at a point in time when the upper end portion of the main body portion MPb is closed by the insulating layer 55, the upper end portion of the end portion EDb still has an opening portion. Consequently, even after the upper end portion of the main body portion MPb is closed, the material gas is supplied into the main body portion MPb from the side surface of the end portion EDb via the opening portion of the end portion EDb and the void SD in the end portion EDb. The insulating layer 55 is formed in the unfilled portion in the main body portion MPb.

Since the diameter of the bottom of the end portion EDb, which is the joining portion of the end portions EDa and EDb, is defined as explained above, closing of the bottom of the end portion EDb can also be delayed later than closing of the upper end portion of the main body portion MPb. Therefore, the opening portion described above of the end portion EDb also communicates with, for example, the inside of the end portion EDa (see FIG. 7B), which is a lower structure of the end portion EDb. The material gas can be supplied to the main body portion of the trenches TRa, which is a lower structure of the main body portion MPb.

The upper end portion of the end portion EDb is not closed until, for example, the inside of the main body portion in a lower part is completely filled by the insulating layer 55. A path for the material gas to the main body portion in the lower part is secured.

Note that, concerning the end portion EDb itself, at a point in time when the upper end portion is closed by the insulating layer 55, for example, the unfilled void SD sometimes remains in the most bulging portion. Depending on a process time, the upper end portion of the end portion EDb is not closed and the void SD remains opened at the upper end portion.

Concerning the end portion EDa, at a point in time when a communicating portion with the end portion EDb is closed, for example, the unfilled void SD sometimes remains in the most bulging portion. Depending on a process time, the void SD of the end portion EDa communicates with the void SD of the end portion EDb.

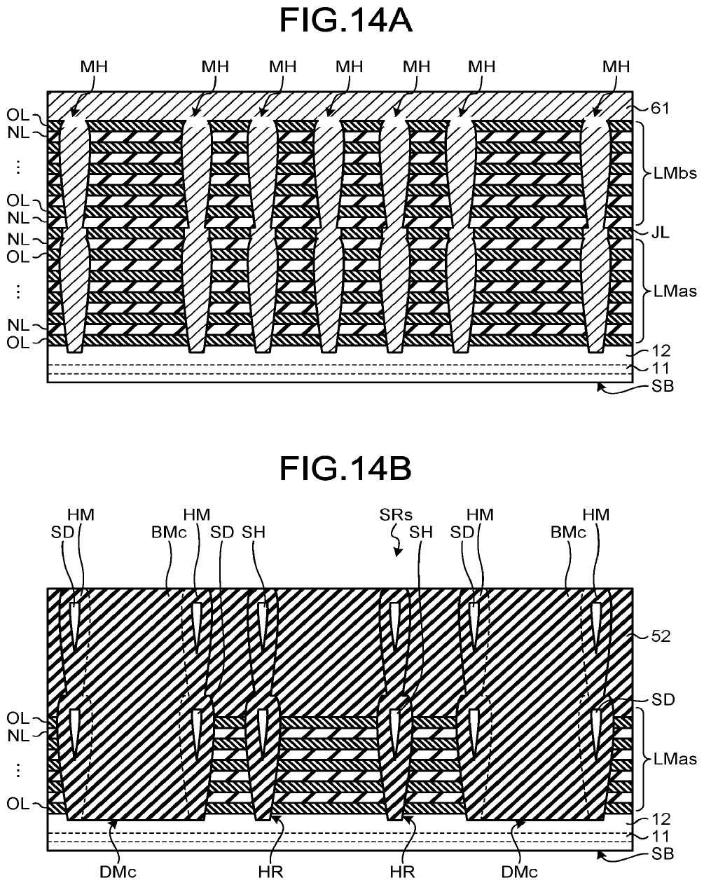

As illustrated in FIG. 14A, in a state in which the memory holes MH are closed by a mask 61, as illustrated in FIG. 14B, an insulating layer is filled in the holes HL and the trenches TR, whereby the columnar bodies HR and plate-like portions DMc are respectively formed. Each of the plate-like portions DMc has a configuration including a beam portion BMc in which two beam portions BM to be opposed to each other with the contact LI interposed therebetween later are coupled and including the columnar portions HM respectively at both ends of the beam portion BMc. As explained above, the columnar portion HM sometimes includes the void SD. The columnar body HR also sometimes includes the void SH.

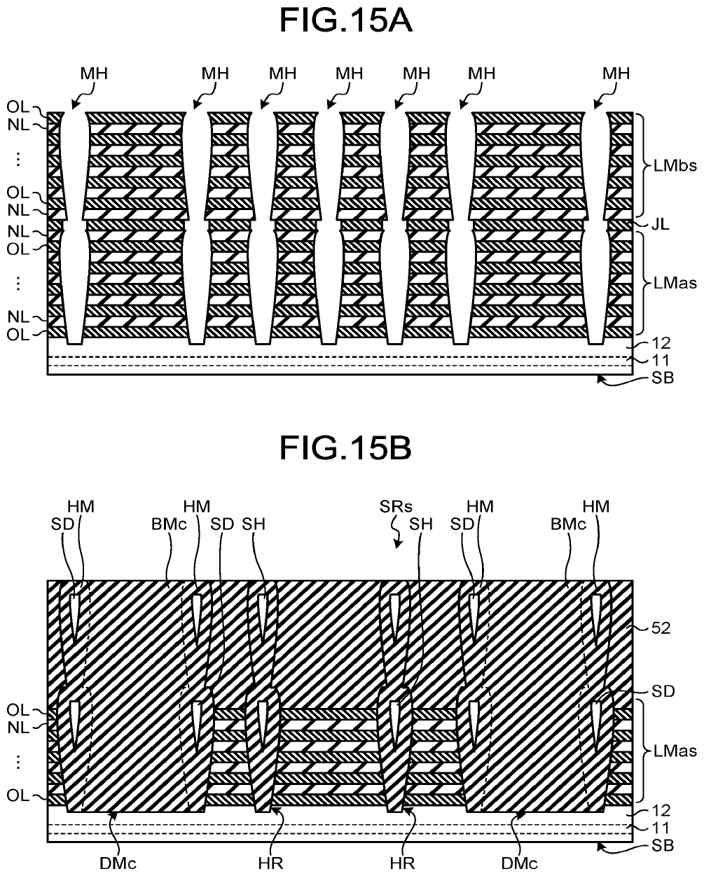

As illustrated in FIG. 15A, the mask 61 in the memory holes MH is removed.

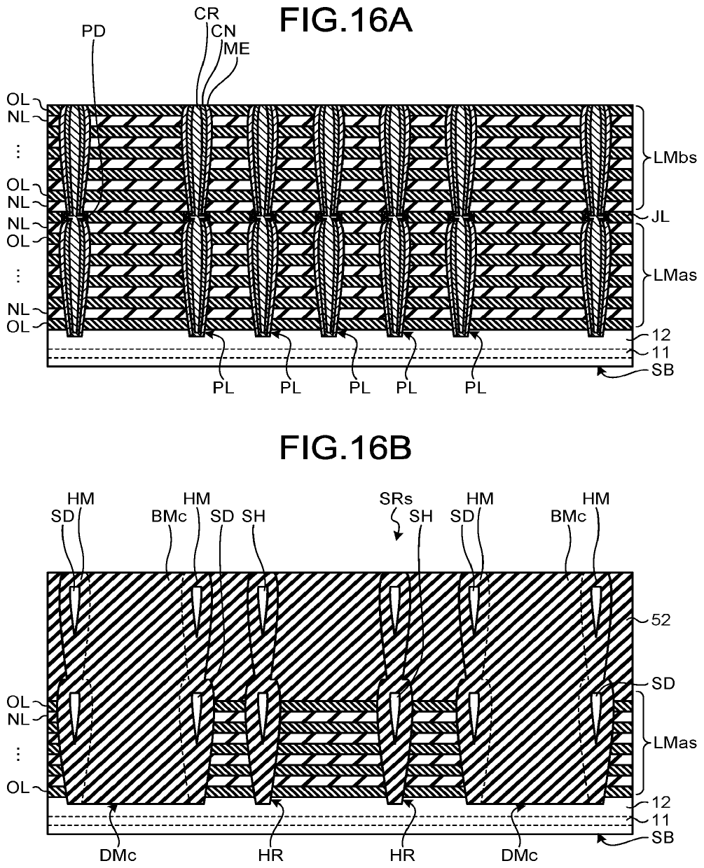

As illustrated in FIG. 16A, the pillars PL are formed in the stacked bodies LMas and LMbs. That is, in order from an inner wall of the memory hole MH, the memory layer ME such as an SiO₂ layer/an SiN layer/an SiO₂ layer, the channel layer CN such as an amorphous silicon layer or a polysilicon layer, and the core layer CR such as an SiO₂ layer are formed. The channel layer CN is also formed in the bottom of the memory hole MH. Consequently, the pillar PL including the pedestal PD in the center is formed.

Note that implementation order of steps illustrated in FIGS. 13A to 13C and FIGS. 14A and 14B and steps illustrated in FIGS. 15A and 15B and FIGS. 16A and 16B can be changed.

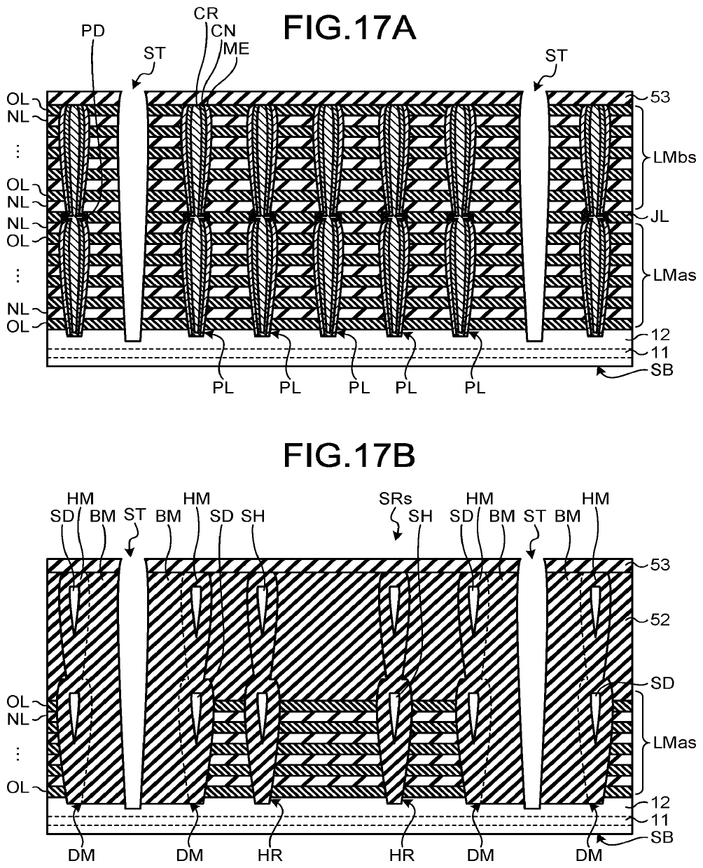

As illustrated in FIGS. 17A and 17B, the insulating layer 53 is formed in upper layers of the portions. That is, in a part illustrated in FIG. 17A, the insulating layer 53 is formed on the stacked body LMbs. In a part illustrated in FIG. 17B, the insulating layer 53 is formed on the insulating layer 52.

As illustrated in FIG. 17A, slits ST penetrating through the insulating layer 53, the stacked body LMbs, the joining layer JL, and the stacked body LMas and reaching the substrate SB are formed.

As illustrated in FIG. 17B, in the stair portion SRs, the slits ST are formed to penetrate through the insulating layer 53, the insulating layer 52 in an upper layer of the stair portion SRs, and the stair portion SRs and reach the substrate SB. Consequently, the beam portion BMc is divided by the slit ST. Two plate-like portions DM each constituting a unit structure and including the columnar portion HM and the beam portion BM and opposed to each other with the slit ST interposed therebetween are formed from one plate-like portion DMc.

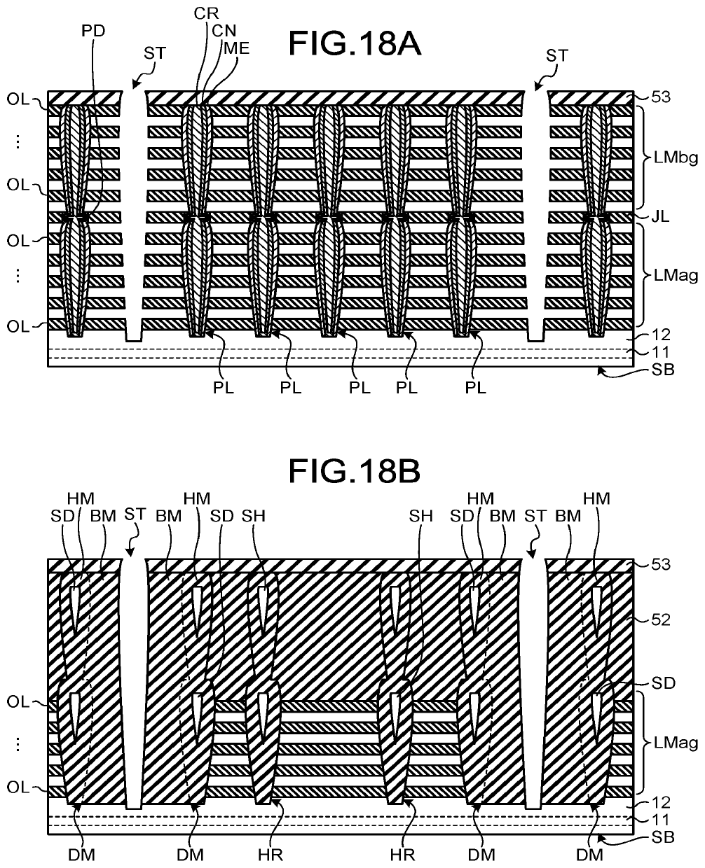

As illustrated in FIGS. 18A and 18B, the sacrificial layers NL in the stacked bodies LMas and LMbs are removed via the slits ST penetrating through the stacked bodies LMas and LMbs. Consequently, stacked bodies LMag and LMbg in which gaps are formed among insulating layers OL are formed.

At this time, in a position illustrated in FIG. 18A, the pillars PL support the stacked bodies LMag and LMbg, which are fragile structures including the gaps. In a position illustrated in FIG. 18B, the columnar bodies HR and the plate-like portions DM support the stacked bodies LMag and LMbg.

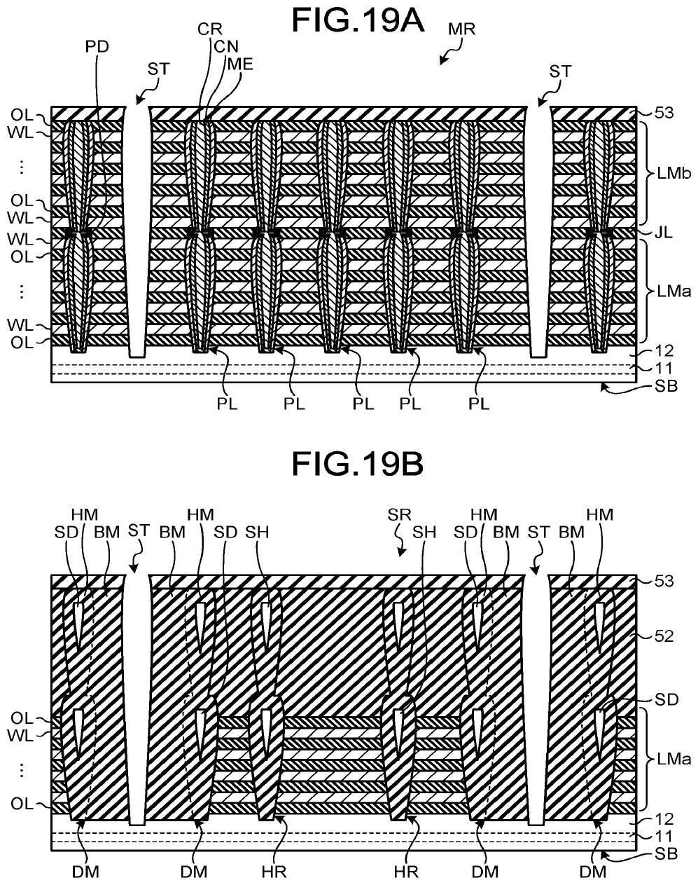

As illustrated in FIGS. 19A and 19B, a conductive material is filled in the gaps in the stacked bodies LMag and LMbg via the slits ST penetrating through the stacked bodies LMag and LMbg. Consequently, the stacked bodies LMa and LMb in which the word lines WL are formed among the insulating layers OL are formed.

As illustrated in FIGS. 18A and 18B and FIGS. 19A and 19B, processing for replacing the sacrificial layers NL with the word lines WL is sometimes called replace.

Thereafter, via the slits ST, the n⁺ diffused region 13 is formed in the substrate SB exposed in the slits ST. The insulating layers 51 are formed on the inner walls of the slits ST. The conductive layers 20 are filled inside the insulating layers 51. Consequently, the contacts LI connected to the n⁺ diffused region 13 are formed.

The contact CC penetrating through the insulating layers 53 and 52 and reaching the word line WL in the top layers of the steps of the stair portion SR is formed.

After the insulating layer 54 covering the memory region MR and the insulating layer 53 of the stair portion SR is formed, the plugs CH penetrating through the insulating layers 54 and 53 and connected to channels CN of the pillars PL and the plugs V0 penetrating through the insulating layer 54 and connected to the respective contacts LI and CC are formed. An upper layer wire and the like connected to the plugs CH and V0 are formed.

Consequently, the semiconductor storage device 1 in the embodiment is manufactured.

In a manufacturing process for a semiconductor storage device such as a three-dimensional nonvolatile memory, a stacked body becomes fragile when a sacrificial layer is removed for replace. Accordingly, a columnar body that supports the stacked body is sometimes disposed in a stair portion or the like. At this time, in order to suppress a bend of layers in a portion facing a slit, it is preferable to dispose the columnar body near the slit.

However, in some cases, the columnar body and the slit come into contact because of misalignment or the like and a void formed on the inside of the columnar body when an insulating layer or the like is filled is opened in the slit. If a conductive layer is filled in this void as well in formation of a word line, a leak current sometimes occurs between the conductive layer and the word line.

When at least one of the columnar body and the slit has a bowing shape, a risk of contact of the columnar body and the slit increases. On the other hand, in some cases, a distance between bottoms of the columnar body and the slit is too large and a bent may occur in the layers of the stacked body.

With the semiconductor storage device 1 in the embodiment, the plate-like portions DM include the columnar portions HM at the end portions farther from the contacts LI. Consequently, it is possible to set the beam portions BM in contact with the contacts LI while sufficiently separating the columnar portions HM, which is likely to have the voids SD, from the contacts LI. Therefore, it is possible suppress a bend of the insulating layers OL in portions facing the contacts LI and increase the strength of the stacked bodies LMa and LMb.

With the semiconductor storage device 1 in the embodiment, the diameter of the bottom surface of the columnar portion HM is larger than the width of the widest portion of the beam portion BM. Consequently, even after the upper end portion of the main body portion MPb of the trench TRb to be the beam portion BM is closed, the material gas of the insulating layer, which is a filler, is supplied through the opening of the end portion EDb of the trench TRb to be the columnar portion HM. Accordingly, the void is suppressed from remaining in the beam portion BM. Therefore, even if a divided surface of the beam portion BM by the slit ST is exposed in the slit ST, the conductive layer is not filled. It is possible to suppress a leak current from occurring between the conductive layer and the word line.

With the semiconductor storage device 1 in the embodiment, the diameter of the upper surface of the columnar portion HM is larger than the width of the widest portion of the beam portion BM and can be set to, for example, size twice as large as the width of the widest portion. Consequently, the diameter of the bottom surface of the columnar portion HM can be configured to be larger than the width of the widest portion of the beam portion BM.

(Modification 1)

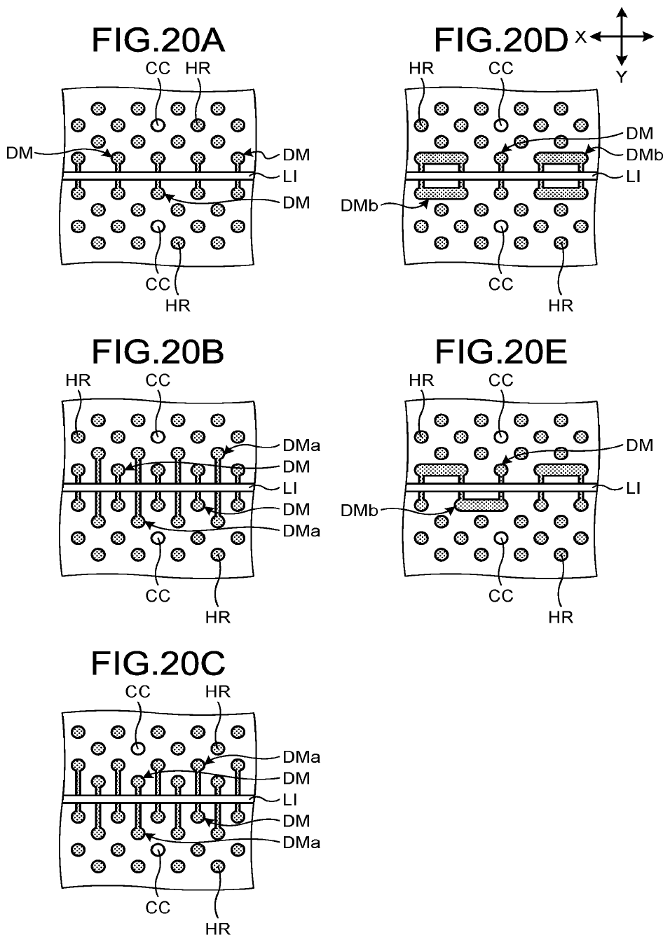

A semiconductor storage device in a modification 1 of the embodiment is explained with reference to FIGS. 20A to 20E. FIGS. 20A to 20E are cross sectional views in a height position of a plate-like portion of a semiconductor storage device according to a modification 1 of the embodiment. In the semiconductor storage device in the modification 1, an arrangement pattern of the plate-like portion is different from the arrangement pattern in the embodiment.

The plate-like portions DM in the embodiment explained above are illustrated in FIG. 20A. As illustrated in FIG. 20A, the columnar portions of the plate-like portions DM have, for example, substantially the same diameter as the diameter of the columnar bodies HR and are arranged to, for example, maintain regular arrangement of the columnar bodies HR. The beam portions of the plate-like portions DM are coupled to the columnar portions of the plate-like portions DM respectively and have longitudinal directions in the Y direction individually in top view. In the embodiment illustrated in FIG. 20A, the beam portions of the plate-like portions DM have substantially the same length along the respective longitudinal directions.

In an example illustrated in FIG. 20B, the plate-like portions DM in the embodiment and plate-like portions DMa including beam portions longer than the beam portions of the plate-like portions DM are alternately arranged along the contact LI. At this time, the plate-like portions DM are opposed to the plate-like portions DM with the contact LI interposed therebetween, and the plate-like portions DMa are opposed to the plate-like portions DMa with the contact LI interposed therebetween.

In an example illustrated in FIG. 20B as well, the columnar portions of each of the plate-like portions DM and DMa have, for example, substantially the same diameter as the columnar bodies HR and are arranged to, for example, maintain regular arrangement of the columnar bodies HR.

In an example illustrated in FIG. 20C as well, the plate-like portions DM in the embodiment and the plate-like portions DMa are alternately arranged along the contact LI. However, in the example illustrated in FIG. 20C, the plate-like portions DM and the plate-like portions DMa are opposed to each other with the contact LI interposed therebetween.

In this case, in a state in which the plate-like portions DM and the plate-like portions DMa before slit formation are coupled, plate-like portions having the same shape including beam portions having the same length are arranged zigzag along the X direction. That is, in forming the plate-like portions before division, one kind of a mask pattern only has to be prepared.

In the example illustrated in FIG. 20C as well, the columnar portions of each of the plate-like portions DM and DMa have, for example, substantially the same diameter as the diameter of the columnar bodies HR. Although an array pattern is different from the array pattern in the examples illustrated in FIGS. 20A and 20B, the columnar portions of each of the plate-like portions DM and DMa are arranged to, for example, maintain regular arrangement of the columnar bodies HR.

In an example illustrated in FIG. 20D, a plate-like portion DMb includes a columnar portion having an elliptical or oval shape extending along the X direction and includes, near both end portions of the columnar portion, two beam portions each extending toward the contact LI and having a longitudinal direction in the Y direction in top view.

At this time, the plate-like portion DM in the embodiment including only one beam portion may be disposed between the plate-like portions DMb as appropriate. Consequently, it is possible to suppress a flow of gas used during replace from being excessively hindered by the plate-like portion DMb forming a region surrounded in a U shape on the contact LI side.

In an example illustrated in FIG. 20E, the beam portion at one end or both ends of the plate-like portion DMb is opposed to the beam portion of the plate-like portion DM with the contact LI interposed therebetween. By combining the plate-like portion DMb and the plate-like portion DM on both sides of the contact LI as appropriate in this way, the flow of the gas during the replace is also easily kept.

(Modification 2)

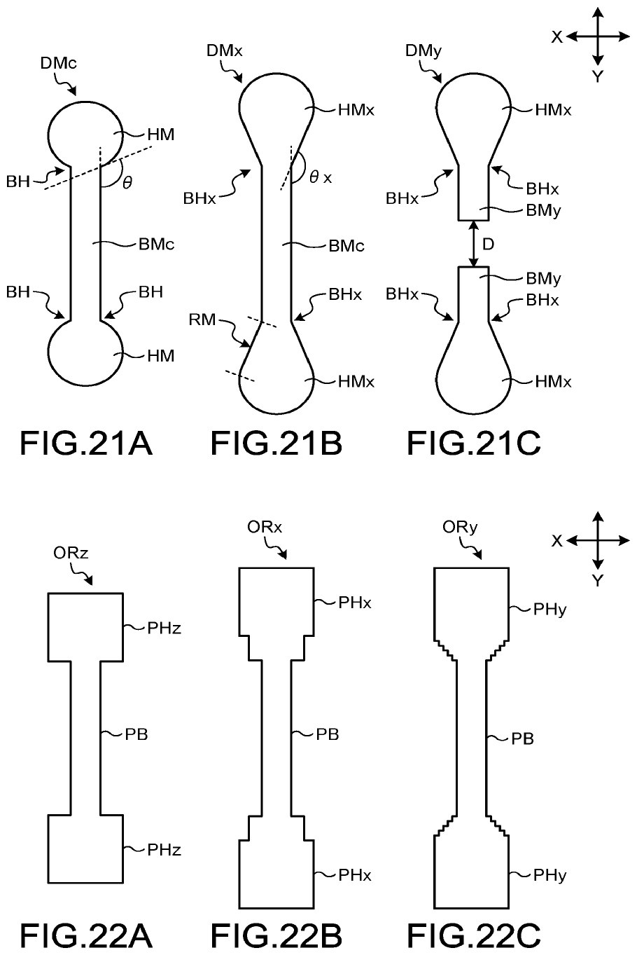

A semiconductor storage device in a modification 2 of the embodiment is explained with reference to FIGS. 21A to 21C and FIGS. 22A to 22C. In the modification 2, a shape for facilitating a flow of a material gas when filling an insulating layer is considered.

FIGS. 21A to 21C are schematic diagrams illustrating a shape viewed from an upper surface of a plate-like portion included in, during a manufacturing process, a semiconductor storage device according to a modification 2 of the embodiment, and specifically, FIGS. 21A to 21C illustrate a shape of the plate-like portion before division by a slit.

The plate-like portion DMc in the embodiment explained above is illustrated in FIG. 21A. As illustrated in FIG. 21A, the plate-like portion DMc includes coupling portions BH in portions where the columnar portions HM and the beam portion BMc are coupled. At this time, if the columnar portions HM have a substantially perfect circular shape in top view, an angle θ formed by the columnar portions HM and the beam portion BMc in the coupling portions BH can be defined as an angle formed by a tangential line in the coupling portions BH of the circular shape and the beam portion BMc. According to such a definition, the angle θ is obtuse.

As explained above, when the insulating layer is filled, after the upper end portion of the main body portion MPb of the trench TRb to be the beam portion BMc is closed, the insulating layer is considered to be formed in the main body portion MPb by the material gas flowing in from the end portion EDb to be the columnar portion HM. At this time, a way of flowing of the material gas in the coupling portions BH is surmised to depend on the angle θ.

In an example illustrated in FIG. 21B, a plate-like portion DMx has a shape obtained by coupling columnar portions HMx of a tear drop shape in top view and the beam portion BMc. That is, the columnar portions HMx have a shape in which an outer edge portion forming a largest diameter near the center gradually narrows toward the beam portion BMc.

Accordingly, in the coupling portion BHx of the columnar portions HMx and the beam portion BMc, the columnar portions HMx are coupled to the beam portion BMc at a gentler angle than, for example, the angle in the coupling portions BH of the plate-like portions DMc in the embodiment. If a segment RM of an outer edge portion from a portion forming a largest diameter to a coupling portion BHx is formed in a substantially linear shape, an angle θx formed by the columnar portions HMx and the beam portion BMc in the coupling portion BHx can be defined as an angle formed by the segment RM and the beam portion BMc. According to such a definition, the angle θx is obtuse and larger than the angle θ.

Since the columnar portions HMx and the beam portion BMc are coupled at the gentle angle in this way, the material gas more smoothly flows into the main body portion MPb of the trench TRb to be the beam portion BMc from the end portions to be the columnar portions HMx. The inflow of the material gas is considered to be facilitated.

In an example illustrated in FIG. 21C, a plate-like portion DMy includes a beam portion BMy divided from the beginning before division by a slit. Consequently, the distance from the columnar portions HMx to divided end portions of the beam portion BMy decreases. A larger amount of the material gas easily reaches the divided end portions of the beam portion BMy.

In this way, in addition to or instead of forming the coupling angle of the columnar portions HMx and the beam portion BMc gentle, by dividing the beam portion BMy from the beginning, it is possible to further suppress a void from forming in the beam portion BMy.

Note that a distance D between two beam portions BMy which are divided and opposed to each other is preferably smaller than, for example, slit width. Consequently, even when misalignment of the slit occurs in the Y direction, it is possible to more surely set the two beam portions BMy in contact with the slit.

However, if the beam portions BMy and the slit are at a close distance, the beam portions BMy do not always have to be in contact with the slit. To be close means a state in which the beam portions BMy and the slit are not in contact but the distance between the beam portions BMy and the slit is short to the extent of making it possible to suppress a bend of the layers of the stacked body.

In the configuration in which the beam portion BMy is divided from the beginning, for example, the plate-like portions DMy do not have to be disposed in opposed positions with the slit interposed therebetween. The respective plate-like portions DMy on both sides of the slit may be disposed to be shifted from each other by a predetermined period or may be disposed at random.

Examples of original plates of mask patterns for forming the columnar portions HMx of the tear drop shape explained above are illustrated in FIGS. 22A to 22C. FIGS. 22A to 22C are schematic diagrams illustrating shapes viewed from upper surfaces of original plates of mask patterns used during the manufacturing process of the semiconductor storage device according to the modification 2 of the embodiment.

In FIG. 22A, an original plate ORz of a mask pattern for forming a plate-like portion BMc in the embodiment is illustrated. As illustrated in FIG. 22A, the original plate ORz has a shape obtained by, for example, coupling, to both end portions of a rectangular pattern PB extending slimly in the Y direction, square patterns PHz having a width larger than the width of the rectangular pattern PB.

By exposing and developing a mask using such an original plate ORz, a mask pattern having substantially the same shape as the shape of the plate-like portion BMc in the embodiment is obtained. That is, a rounded mask pattern and the circular columnar portion HM are formed from the square patterns PHz. The beam portion BMc is formed from the rectangular pattern PB.

For example, as illustrated in FIG. 21B, to form the columnar portions HMx in the tear drop shape, an original plate ORx illustrated in FIG. 22B can be used.

As illustrated in FIG. 22B, the original plate ORx includes, instead of the square patterns PHz, step-like patterns PHx having a plurality of rectangles. The plurality of rectangles of the step-like pattern PHx is combined such that width gradually decreases toward the rectangular pattern PB.

A step-like portion of the step-like pattern PHx becomes a gentle linear pattern in the mask pattern undergone the exposure and the development. The segment RM of the outer edge portion in the columnar portion HMx is formed.

As illustrated in FIG. 22C, by combining a larger number of rectangles to form the step-like pattern PHy, the shape of the segment RM of the columnar portion HMx becomes smoother.

(Other Modifications)

In the embodiment and the modifications 1 and 2, the semiconductor storage device 1 includes the plate-like portions BM and the like in the stair portion SR. However, a semiconductor storage device may include plate-like portions in a memory region, between memory regions, or the like.

In the embodiment and the modifications 1 and 2, the semiconductor storage device 1 includes a two-tier (two-step) structure including the two stacked bodies LMa and LMb. However, a semiconductor storage device may include a one-tier or three-tier or more structure.

In the embodiment and the modifications 1 and 2, the semiconductor storage device 1 is disposed on the substrate SB such as a silicon substrate. However, a stacked body of a semiconductor storage device including a memory region and a stair portion may be stacked above a peripheral circuit disposed on a substrate or may be bonded to the substrate on which the peripheral circuit is disposed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a stacked body including a plurality of conductive layers stacked with an insulating layer interposed therebetween, end portions of the plurality of conductive layers being arranged like stairs in a stair portion;
a pillar extending in a stacking direction of the plurality of conductive layers in the stacked body;
a plurality of memory cells each disposed in a crossing portion of at least a part of the plurality of conductive layers and the pillar;
a first structure that has a longitudinal direction in a first direction crossing the stacking direction and divides the stacked body; and
a second structure that is disposed in the stair portion, extends in a second direction toward the first structure from a position apart from a side surface of the first structure and extends in the stacking direction in the stacked body, wherein
a width of the second structure is wider at a first portion farther from the first structure than at a second portion closer to the first structure, and
the second portion has a longitudinal direction in the second direction in top view.

2. The semiconductor storage device according to claim 1, wherein
the second portion is in contact with or close to the side surface of the first structure.

3. The semiconductor storage device according to claim 1, wherein
the first portion includes
a curved surface from a first part, through a second part, to a third part, the first part being closer to the second portion, and having a width substantially equal to a width of the second portion, the second part having the largest width in the first portion, the first portion terminating at the third part opposite to the second portion.

4. The semiconductor storage device according to claim 3, wherein
the first portion has
a substantially circular shape in which the first part is opened toward the second portion in top view.

5. The semiconductor storage device according to claim 3, wherein
the first portion has
a shape of a tear drop in which the curved surface from the first part to the second part is gentler than the curved surface from the second part to the third part and the first part is opened toward the second portion in top view.

6. The semiconductor storage device according to claim 1, wherein
the second structure includes,
as the second portion, a beam portion extending toward the first structure, and,
as the first portion, a columnar portion coupled to the beam portion.

7. The semiconductor storage device according to claim 6, wherein
an angle at a coupling portion of the beam portion and the columnar portion is obtuse.

8. The semiconductor storage device according to claim 7, wherein
the columnar portion has,
in top view, a substantially circular shape coupled to the beam portion or a shape of a tear drop gradually narrowed toward the beam portion and coupled to the beam portion.

9. The semiconductor storage device according to claim 8, wherein,
the columnar portion has the shape of the tear drop, the angle at the coupling portion being larger than the columnar portion of the circular shape.

10. The semiconductor storage device according to claim 1, wherein
the second structure includes,
as the second portion, a first beam portion extending in the second direction,
a second beam portion that is a third portion closer to the first structure, extends in the second direction in a position apart from the first beam portion, extends in the stacking direction in the stacked body, and has a width substantially equal to the first beam portion, and,
as the first portion, a columnar portion coupled to the first beam portion and the second beam portion.

11. The semiconductor storage device according to claim 10, wherein
the columnar portion has
in top view, an elliptical shape or an oval shape coupled to the first beam portion and the second beam portion, the elliptical shape or the oval shape having a major axis along a direction crossing the second direction.

12. The semiconductor storage device according to claim 1, wherein
the second structure includes a plurality of unit structures disposed in positions opposed to each other with the first structure interposed therebetween.

13. The semiconductor storage device according to claim 12, wherein
the plurality of unit structures includes
a first unit structure having a first length in the second direction, and
a second unit structure having a second length longer than the first length in the second direction, and having the first portion located in a position farther from the first structure than the first portion of the first unit structure.

14. The semiconductor storage device according to claim 13, wherein
the first unit structure includes a plurality of first unit structures,
the second unit structure includes a plurality of second unit structures,
one first unit structure of the plurality of first unit structures is disposed in a position opposed to another first unit structure of the plurality of first unit structures with the first structure interposed therebetween, and
one second unit structure of the plurality of second unit structures is disposed in a position opposed to another second unit structure of the plurality of second unit structures with the first structure interposed therebetween.

15. The semiconductor storage device according to claim 13, wherein
the second unit structure is disposed in a position opposed to the first unit structure with the first structure interposed therebetween.

16. The semiconductor storage device according to claim 1,
wherein,
the second structure includes the first portion farther from the first structure and two second portions closer to the first structure, the two second portions being coupled to the first portion at positions disposed in a direction crossing the second direction.

17. The semiconductor storage device according to claim 1, wherein
a width of an upper surface of the first portion is larger than a width of a portion of the second portion where the second portion is widest in the stacking direction.

18. The semiconductor storage device according to claim 17, wherein
a width of a bottom surface of the first portion is larger than the width of the portion of the second portion where the second portion is widest in the stacking direction.

19. The semiconductor storage device according to claim 17, wherein
a width of a portion of the first portion where the first portion is narrowest in the stacking direction is larger than the width of the portion of the second portion where the second portion is widest in the stacking direction.

20. The semiconductor storage device according to claim 19, wherein,
in a cross section in a width direction of the second structure, the first portion and the second portion each have a bowing shape bulged between an upper surface and a bottom surface.
